(19) United States
(12) Patent Application Publication
(10) Pub. No.: US 2008/0129301 A1
(43) Pub. Date: Jun. 5, 2008

(54) Method of detecting and verifying installed circuit breaker architecture

(76) Inventor: Jason Edward Harmon, Bristol, CT (US)

Correspondence Address: Paul D. Greeley;Ohlandt, Greeley, Ruggiero & Perle, L.L.P., 10th Floor, One Landmark Square, Stamford, CT, 06901-2682, US

(21) Appl. No.: 11/606,436

(22) Filed: Nov. 30, 2006

(51) Int. Cl. G01R 31/327

(52) U.S. Cl. 324/424

(57) ABSTRACT

A method of detecting or validating the architecture of a circuit breaker unit disposed within a circuit breaker assembly comprising a plurality of the circuit breaker units, the method comprising: tagging each the circuit breaker unit with an identification tag, the identification tag providing architectural information related to the circuit breaker; and reading the identification tag disposed on the circuit breaker, whereby the circuit breaker assembly does not need to be disassembled for detection or validation of the architecture of the circuit breaker.

### BACKGROUND

1. Field

The present disclosure generally relates to a novel method of detecting and/or verifying the installed circuit breaker architecture without removal of front panel or disassembly of multiple circuit breaker assembly. In particular, the present disclosure relates to using wireless readers to determine the unique architecture in each circuit breaker unit.

2. Discussion of the Background Art

Conventional circuit breakers are typically factory assembled into a plurality of side-by-side circuit breaker units. The problem is that once assembled it is impossible to quickly determine which circuit breaker units have been assembled together and whether they have been assembled in the correct order. Any determination would require disassembly of the plurality of units or removal of each circuit breaker's front panel. Both of which are incredibly time consuming and labor intensive.

Moreover, if the factory assembled circuit breaker is shipped to customers without checking the individual circuit breakers included therein and the sequence of circuit breakers, it causes frustration with customers, as well as results in increased installation and reinstallation costs, downtime for the customer and reduced profit margins to the manufacturer.

Conventional circuit breaker assemblies also do not allow service personnel to easily determine the architecture of a particular circuit breaker without disassembly of the circuit breaker units or removal of the panelboard from each circuit breaker. Again, this is very labor intensive and costly for the customer or service provider. Conventional detection and verification of a particular circuit breaker architecture in conducted manually by the service or installation personnel.

The present inventors have recognized that the disposition of the circuit breaker identification tag 2, e.g., barcode, in conventional circuit breaker units 4, such as that shown in FIGS. 1 and 2, disposed on the sidewall 6 of each circuit breaker unit 4. When assembled the identification tag 2 is hidden from view, as it is disposed such that it is covered by the sidewall 4 of the immediately adjacent circuit breaker unit 4. See FIG. 3a wherein the identification tag 2 is out of sight and not visible from panelboard 8

The present inventors have uniquely designed a circuit breaker identification system that avoids the disadvantages of the prior art designs. In particular, the present disclosure provides for the reduction or elimination in the shipping of products which do not meet customer specifications and also provides for a more efficient manufacturing process. In addition, customer satisfaction would be greatly enhanced, as the issue of the wrong breaker being installed in customer equipment or the wrong breaker being order as a replacement for defective or faulty equipment would be drastically reduced or eliminated. All of which will result in substantial installation, manufacturing and repair costs associated with circuit breaker assemblies. Finally, the present invention would greatly reduce the labor cost of inspecting, servicing and manufacturing of circuit breaker assembly, by providing rapid and quick identification of a particular circuit breaker's architecture, with the need for disassembly of the circuit breaker assembly or panelboard of each circuit breaker unit.

The present disclosure also provides many additional advantages, which shall become apparent as described below.

### SUMMARY

A method of detecting or validating the architecture of a circuit breaker unit disposed within a circuit breaker assembly comprising a plurality of the circuit breaker units, the method comprising: tagging each the circuit breaker unit with an identification tag, the identification tag providing architectural information related to the circuit breaker; and reading the identification tag disposed on the circuit breaker, whereby the circuit breaker assembly does not need to be disassembled for detection or validation of the architecture of the circuit breaker. The method further comprising: detecting or validating the architecture of the circuit breaker based upon the identification tag.

Preferable the identification tag is at least one tag selected from the group consisting of: a barcode, RFID, or any similar wireless identification device. The identification tag is read by at least one reader selected from the group consisting of: barcode reader, RFID reader, or any similar wireless scanning or reading device.

Another embodiment includes a method of detecting or validating the architecture of a circuit breaker unit disposed within a circuit breaker assembly comprising a plurality of the circuit breaker units, the method comprising: transmitting an identification signal from the circuit breaker unit, the identification signal providing architectural information related to the circuit breaker; and receiving the identification signal transmitted from the circuit breaker, whereby the circuit breaker assembly does not need to be disassembled for detection or validation of the architecture of the circuit breaker. The method further comprising: detecting or validating the architecture of the circuit breaker.

Preferably, the identification signal is transmitted by an electronic signal emitter or similar signal transmitting device. The identification signal is received by an electronic signal receiver or similar electronic signal receiving device.

Further objects, features and advantages of the present disclosure will be understood by reference to the following drawings and detailed description.

### BRIEF DESCRIPTION OF THE DRAWINGS

FIGS. 1 and 2 are side perspective view of conventional circuit breaker units having barcode identification tags or labels disposed on their sidewalls;

FIG. 3a is a front planar view of a conventional circuit breaker assembly panelboard having a plurality of circuit breaker unit disposed side-by-side;

FIG. 3b is circuit breaker assembly panelboard depicting the identification barcode tag disposed on one of the front panelboards of the circuit breaker units in accordance with the present disclosure, although individual identification barcode tags are preferably disposed on each circuit breaker unit;

FIG. 4 is a front planar view of other circuit breaker assembly having identification barcode tags dispose on the front panelboard of each circuit breaker unit;

FIGS. 5 and 6 are the same circuit breaker assemblies show in FIGS. 3b and 4, however, the identification barcode tags have been replaced with other electronic identification tags, such as infrared identification (RFID) tags;

FIG. 7 is a schematic representation of a circuit breaker assembly and a wireless reader according to the present disclosure.

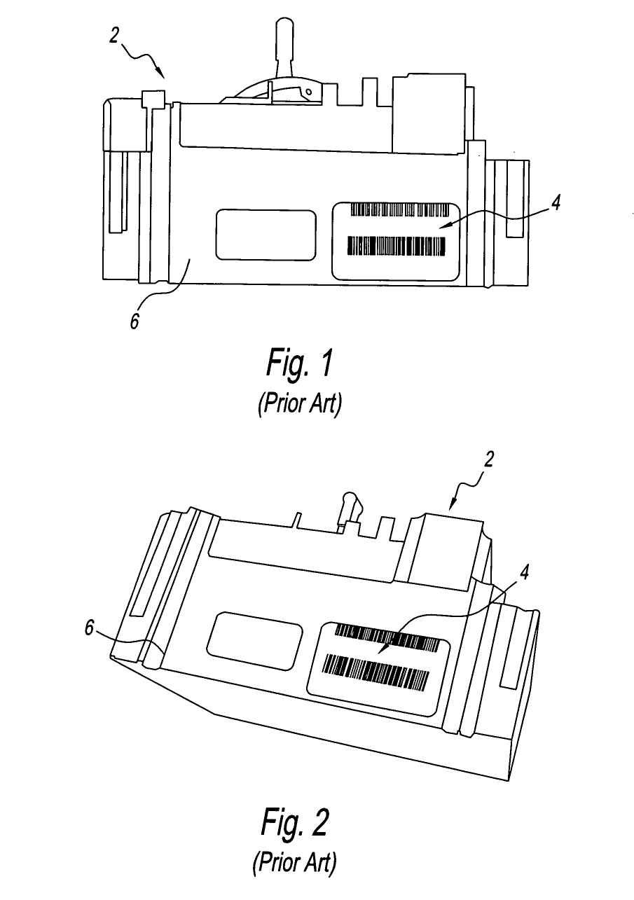

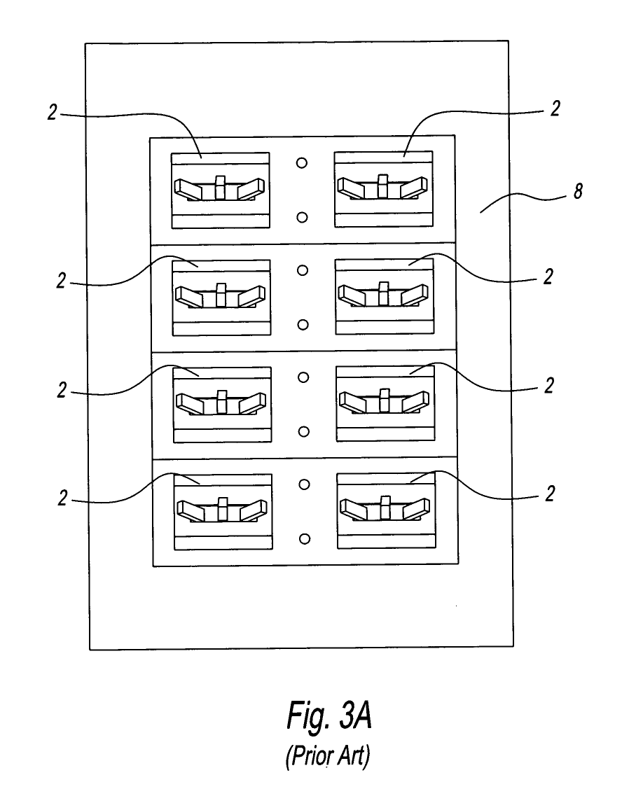

### DETAILED DESCRIPTION OF THE PREFERRED EMBODIMENT

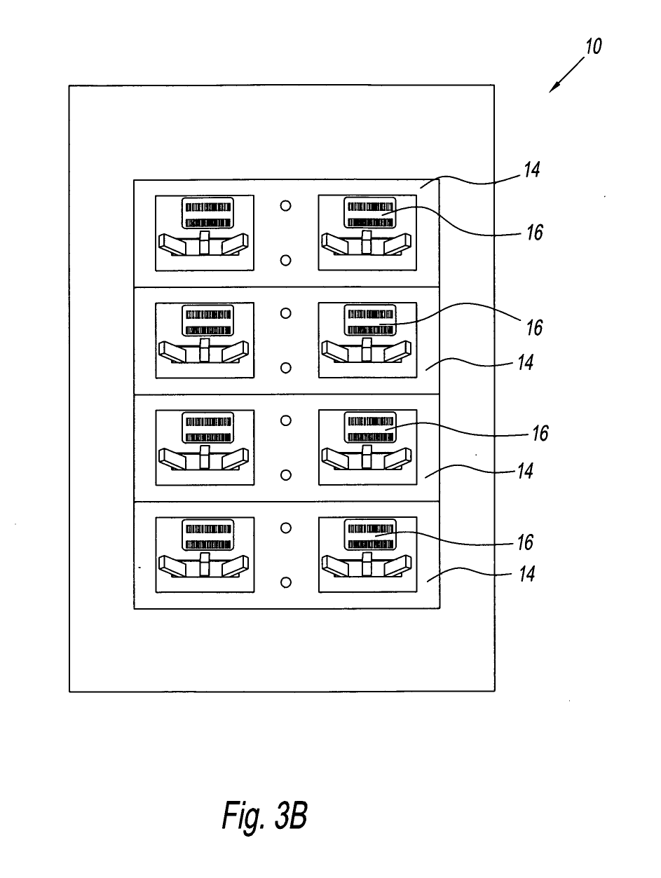

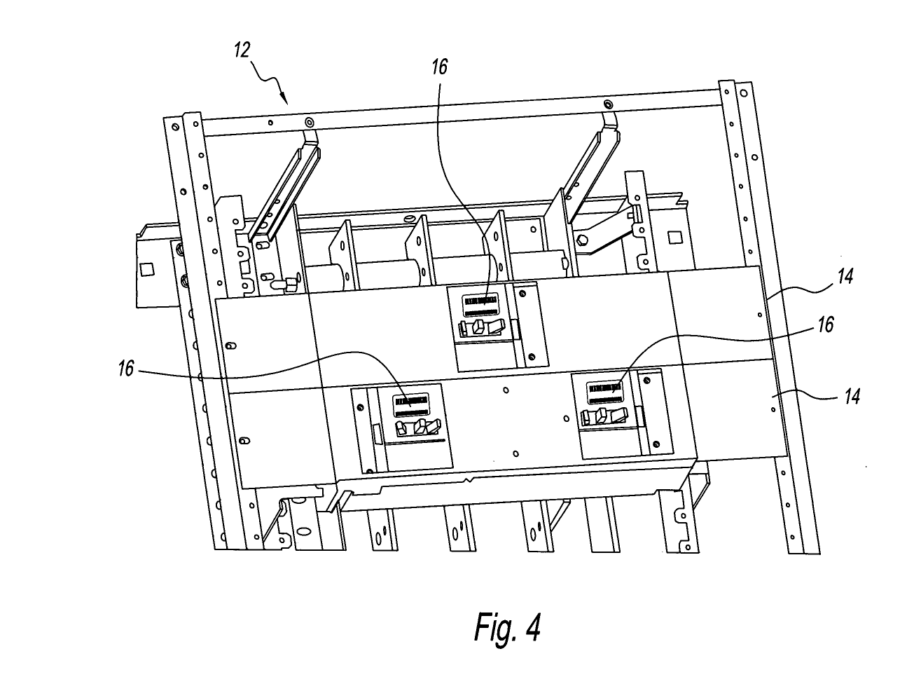

The present disclosure can best be describe by referring to the figures, wherein FIGS. 3B and 4 depict respective circuit breaker assemblies 10 and 12 comprised of a plurality of circuit breaker units 14, wherein each circuit breaker unit 14 has an associated identification tag 16, e.g., a barcode, which provides a service or manufacturing technician with information specific to each unique circuit breaker unit, including its specific architecture.

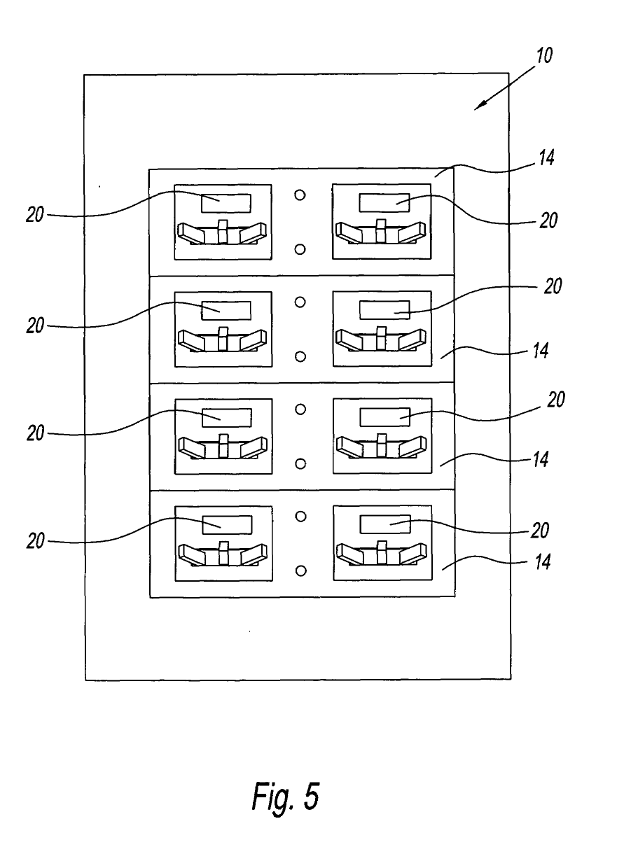

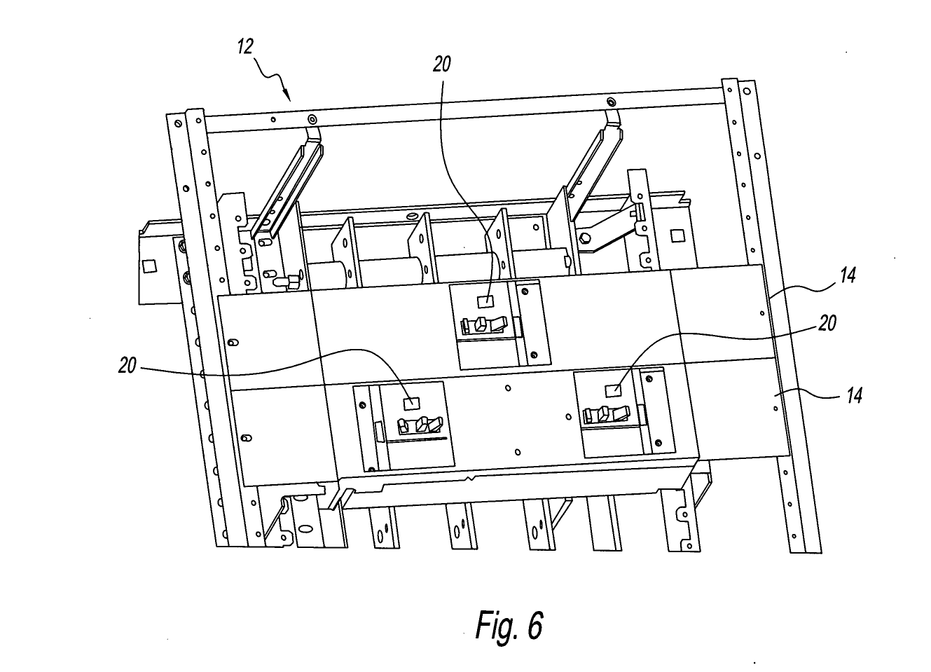

FIGS. 5 and 6 are correspond to FIGS. 3b and 4, respectively, except that the identification tag 20 in each of these FIGS. 5 and 6 is preferably an RFID.

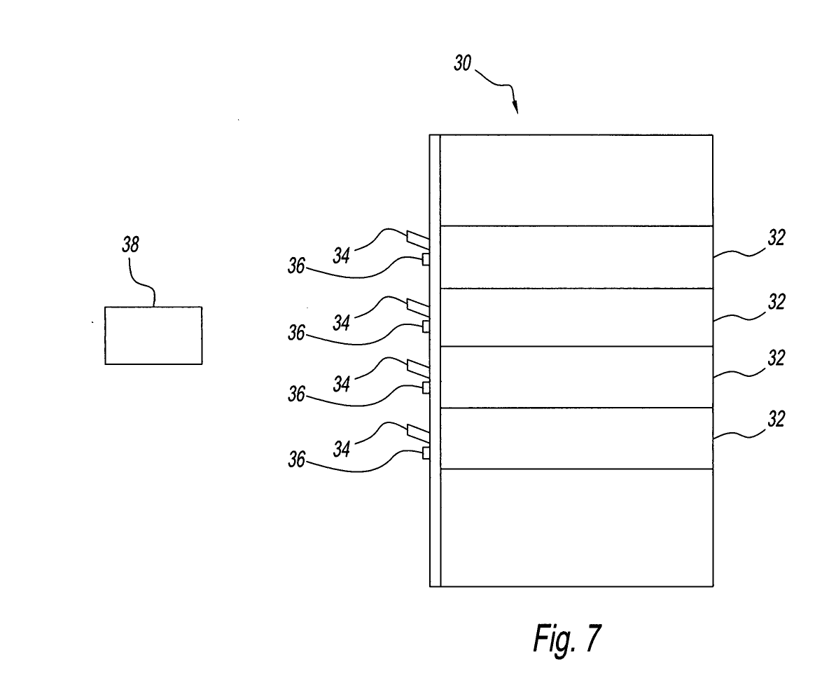

FIG. 7 depicts a circuit breaker assembly 30 comprising a plurality of circuit breaker units 32, wherein the architecture of each circuit breaker unit 32 can be either the same or different. Each circuit breaker unit 32 includes a switch 34 and an identification tag 36, such as an RFID. Identification tags 36 can be individually read by wireless reader 38 or similar technology, such that it can determine the specific architecture of each circuit breaker unit 32, thereby allowing the manufacture to confirm that circuit breaker assembly 30 has been assembled with the correct circuit breaker units and in the proper sequence. Alternatively, a service technician will be able to use a hand-held or automated reader 38 on-site to confirm the architecture of each circuit breaker unit 32, without having to disassemble circuit breaker assembly 30 or removal of front panelboard 40.

While we have shown and described several embodiments in accordance with our invention, it is to be clearly understood that the same may be susceptible to numerous changes apparent to one skilled in the art. Therefore, we do not wish to be limited to the details shown and described but intend to show all changes and modifications that come within the scope of the appended claims.

What is claimed is:

1. A method of detecting or validating the architecture of a circuit breaker unit disposed within a circuit breaker assembly comprising a plurality of said circuit breaker units, said method comprising:
tagging each said circuit breaker unit with an identification tag, said identification tag providing architectural information related to said circuit breaker; and
reading said identification tag disposed on said circuit breaker, whereby said circuit breaker assembly does not need to be disassembled for detection or validation of said architecture of said circuit breaker.

2. The method according to claim 1 further comprising:
detecting or validating said architecture of said circuit breaker based upon said identification tag.

3. The method according to claim 1, wherein said identification tag is at least one tag selected from the group consisting of: a barcode, RFID, and any wireless identification device.

4. The method according to claim 1, wherein said identification tag is read by at least one reader selected from the group consisting of: barcode reader, RFID reader, and any wireless scanning or reading device.

5. A method of detecting or validating the architecture of a circuit breaker unit disposed within a circuit breaker assembly comprising a plurality of said circuit breaker units, said method comprising:
transmitting an identification signal from said circuit breaker unit, said identification signal providing architectural information related to said circuit breaker; and
receiving said identification signal transmitted from said circuit breaker, whereby said circuit breaker assembly does not need to be disassembled for detection or validation of said architecture of said circuit breaker.

6. The method according to claim 5 further comprising:
detecting or validating said architecture of said circuit breaker.

7. The method according to claim 5, wherein said identification signal is transmitted by an electronic signal transmitter.

8. The method according to claim 5, wherein said identification signal is received by an electronic signal receiver.
